(19) United States
(12) Patent Application Publication
(10) Pub. No.: US 2007/0221131 A1
(43) Pub. Date: Sep. 27, 2007

(54) VAPOR DEPOSITION SOURCE AND VAPOR DEPOSITION APPARATUS

(75) Inventors: TOSHIAKI YOSHIKAWA, YOKOHAMA-SHI (JP); SEIJI MASHIMO, YOKOHAMA-SHI (JP); NAOTO FUKUDA, FUNABASHI-SHI (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 11/686,058

(22) Filed: Mar. 14, 2007

(30) Foreign Application Priority Data
Mar. 22, 2006 (JP) 2006-077948
Feb. 23, 2007 (JP) 2007-043094

(51) Int. Cl. C23C 16/00

(52) U.S. Cl. 118/726

(57) ABSTRACT

An object of the present invention is to reduce splash generated in a vapor deposition source and carry out vapor deposition at a stable, high vapor deposition speed. The vapor deposition according to the present invention is carried out by vertically stacking a plurality of doughnut-shaped flat plates in a crucible, mounting thin vapor deposition material on the doughnut-shaped flat plates, using heaters that surround the crucible to heat the vapor deposition material on the doughnut-shaped flat plates, allowing the vapor generated from the vapor deposition material to flow through a flow space A at each layer into a vertical flow path B, and discharging the vapor from an opening at the top of the flow path B toward a substrate to be deposited. The conductance of the flow space A is smaller than the conductance of the flow path B.

### BACKGROUND OF THE INVENTION

1. Field of the Invention

The present invention relates to a vapor deposition source for a vapor deposition apparatus and a vapor deposition apparatus for forming a film, such as an organic EL pattern for organic elements mounted in an organic EL display.

2. Description of the Related Art

Organic EL displays have received attention as a display device that provides high brightness and low power consumption and replaces liquid crystal displays, and as a future trend of display devices characterized by a thin profile, fast response and wide view angle. Methods for manufacturing organic EL displays are broadly classified into two ways. One method involves using masked vapor deposition to form a film made of low molecular weight organic EL material, while the other method involves forming a rib on a substrate in advance and then using ink jet printing or the like to supply high molecular weight organic EL material into a recess surrounded by the rib.

The approach using ink jet printing or the like to supply high molecular weight organic EL material has not yet reached a commercialization stage because high molecular weight organic EL material to be used is still under development. On the other hand, the approach using vapor deposition has been commercialized in the fields of passive matrix monochrome and area-color panels.

Conventional vapor deposition apparatuses include vapor deposition sources, such as those disclosed in Japanese Patent Publication No. H05-041697 and Japanese Patent Application Laid-Open No. H01-225769. The vapor deposition source disclosed in Japanese Patent Publication No. H05-041697 is adapted, as illustrated in FIG. 5, such that a vapor deposition source 110 is disposed in the lower part of a chamber 121 and the vapor deposition source 110 has an opening 110a that discharges the vapor generated from vapor deposition material 103, such as organic EL film material, in a crucible 101, which is an enclosure. A substrate W₀ supported by a substrate holder 122 is disposed above the opening 110a via a vapor deposition mask 123 supported by a mask holder 124.

In this configuration, when a small scale production system (batch system) is employed, a procedure in which the substrate and the vapor deposition material for one vapor deposition step are loaded for each film forming process is repeated.

When a large scale production system is employed, vapor deposition material for several steps to several hundreds of steps is loaded in advance in the crucible in the vapor deposition source permanently installed in a vapor deposition compartment (chamber) where a vacuum is maintained, and only the substrate is exchanged through a load lock compartment for each vapor deposition step.

Alternatively, Japanese Patent Application Laid-Open No. H04-359508 describes a method in which a plurality of projections is provided on the inner wall of a cylindrical container with an opening and raw material is filled not only at the bottom of the container but also on the projections, followed by heating the container to discharge the raw material. Japanese Patent Application Laid-Open No. H04-359508 describes that even when the amount of the remaining raw material decreases as the raw material is discharged, the impact of the amount of decrease on the discharge of the raw material can be reduced.

However, use of such conventional vapor deposition sources to deposit an organic EL thin film causes the following problems. Many types of organic EL thin film material are sublimation material. When sublimation vapor deposition material is deposited, no convection occurs in the vapor deposition source as in molten material. Thus, the highest temperature occurs in the vapor deposition material that is in contact with the inner wall surface of the vapor deposition source, and this portion generates vapor, which is discharged from the opening of the vapor deposition source into the vacuum chamber.

In general, sublimation organic material has low heat conductivity, so that this tendency becomes stronger. Furthermore, the surface portion (upper part) of the vapor deposition material placed in the vapor deposition source faces the opening of the vapor deposition source. Thus, heat is radiated from the opening of the vapor deposition source into the space so as to lower the temperature of the upper part of the vapor deposition material compared to those of the center and lower parts of the vapor deposition source. As a result, in the vapor deposition source, while the portion along the inner wall surface mainly generates vapor, the upper part of the vapor deposition material behaves as if the upper part were a lid, which blocks smooth desorption of the vapor.

When the vapor of the vapor deposition material is accumulated to reach a certain pressure, the vapor displaces the lid-like upper part of the vapor deposition material and is discharged into the vacuum chamber. The discharge accompanies minute explosions and hence causes a phenomenon called splash (bumping), resulting in various defects in a deposited film. Furthermore, vapor retaining gaps formed along the inner wall of the vapor deposition source will be broken and low-temperature new vapor deposition material will come into contact with the inner wall surface of the vapor deposition source, resulting in temperature variations. This causes instability of the vapor deposition speed of the vapor deposition material.

To eliminate these problems, in Japanese Patent Application Laid-Open No. H01-225769, by uniformly dispersing heat conductive fine particles in the vapor deposition material made of an organic compound, the raw material is heated through heat conduction between the crucible and the organic material, between the crucible and the heat conductive particles, between the individual heat conductive particles and between the organic material and the heat conductive particles. Moreover, by reducing the particle size of the organic material and the heat conductive particles, the respective contact areas are increased for efficient heat transfer.

According to this configuration, while the temperature distribution in the vapor deposition source is improved, heat radiated from the opening of the vapor deposition source lowers the temperature of the upper part of the vapor deposition material compared to the temperature of the lower part of the vapor deposition material, and the vapor generated from the vapor deposition material has to pass through gaps in the vapor deposition material to the top of thereof. When no appropriate passage is present, vapor gas retaining portions are formed as described above, and the vapor will be discharged into the vacuum chamber accompanied with minute explosions when the vapor reaches a certain pressure. Therefore, the configuration described in Japanese Patent Application Laid-Open No. H01-225769 does not solve the problems, such as splash.

In Japanese Patent Publication No. H05-041697, to prevent the decrease in temperature at the upper part of the vapor deposition material, a chimney-shaped tube is provided in the vapor deposition source to allow the upper part of the vapor deposition source to be heated, preventing the decrease in temperature at the upper part of the vapor deposition material. Furthermore, even when splash occurs, the chimney-shaped tube blocks particles generated in association with the splash from reaching the substrate to be deposited, allowing stable vapor deposition.

However, even if the reduction in temperature of the upper part of the vapor deposition material can be eliminated, the vapor of the vapor deposition material generated in the vapor deposition material and at the portion in contact with the inner wall surface of the vapor deposition source is still discharged into the vacuum chamber through the upper part of the vapor deposition material. Thus, the vapor of the vapor deposition material generated in the vapor deposition material and at the portion in contact with the inner wall surface of the vapor deposition source forms gas retaining portions in the vapor deposition material until the vapor reaches a certain pressure, and passes through the chimney-shaped tube, accompanied with minute explosions, to the substrate to be deposited. In this case, the vapor deposition speed becomes unstable as described above.

To prevent such minute explosions of the vapor, it is necessary to quickly eliminate the vapor generated from the vapor deposition material therefrom. Sublimation material often has its sublimation point close to its decomposition point. In this case, the heated area of the vapor deposition material must be large to obtain a high vapor deposition speed. To meet these requirements, it is necessary to place the vapor deposition material in the vapor deposition source in a thin and spread manner. To this end, the vapor deposition source needs to be extremely large, which is not realistic.

Japanese Patent Application Laid-Open No. H04-359508 describes that provision of the projections allows stable discharge of raw material for a long period of time. However, since the raw material placed on the projections is exposed to the substrate to be deposited, particles generated in association with splash could directly attach to the substrate to be deposited. Furthermore, when gas evaporated from the raw material placed on the projections gathers to the flow path at the center of the container and the gas is more resistant to flow through the flow path compared to the gaps above and below the projections, the gas evaporated from the raw material placed on the projections cannot quickly reach the opening.

### SUMMARY OF THE INVENTION

The present invention has been made in view of the unsolved problems that the above prior arts have, and provides a vapor deposition source and a vapor deposition apparatus capable of preventing splash and the like and stably providing a high vapor deposition speed.

The vapor deposition source according to the present invention comprises: an enclosure that houses vapor deposition material therein and has an opening at the top the enclosure for discharging the vapor deposition material after heated; and a plurality of mounting units for mounting vapor deposition material, the plurality of mounting units vertically disposed in the enclosure in a multilayer manner with a gap between each pair of the mounting units, each of the mounting units being a planar member and having a hole therein.

The gap forms a flow space in the in-plane direction of the mounting unit for guiding the vapor generated from the mounted vapor deposition material to the opening of the enclosure.

The holes of the mounting units form a vertical flow path that connects the flow spaces to the opening of the enclosure.

The conductance of the flow space is smaller than the conductance of the flow path.

The plurality of vapor deposition material mounting units is stacked and the vapor deposition material is heated and evaporated in the limited area at each layer, so that a large evaporation area can be obtained without increasing the size of the vapor deposition source.

The vapor deposition material is mounted in a thin and spread manner for evaporation, allowing vapor to be generated from the vapor deposition material without minute explosions that causes splash and the like. Furthermore, the large area for heating the vapor deposition material allows a stable, high vapor deposition speed without increasing the temperature.

Moreover, the conductance of the flow space is smaller than the conductance of the flow path, so that the vapor generated from the vapor deposition material mounted on the mounting units can quickly reach the opening of the enclosure, allowing more stable vapor deposition.

Further features of the present invention will become apparent from the following description of exemplary embodiments with reference to the attached drawings.

### BRIEF DESCRIPTION OF THE DRAWINGS

FIG. 1 is a diagrammatic cross-sectional view illustrating the vapor deposition source according to the first embodiment.

FIG. 2 is a diagrammatic cross-sectional view illustrating a vapor deposition apparatus using the vapor deposition source according to the first embodiment.

FIG. 3 is an exploded cross-sectional view illustrating the vapor deposition source according to the second embodiment.

FIG. 4 is a cross-sectional assembly view illustrating the vapor deposition source according to the second embodiment.

FIG. 5 is a diagrammatic cross-sectional view illustrating a vapor deposition apparatus according to a conventional embodiment.

### DESCRIPTION OF THE EMBODIMENTS

Exemplary embodiments for carrying out the present invention will be described with reference to the drawings.

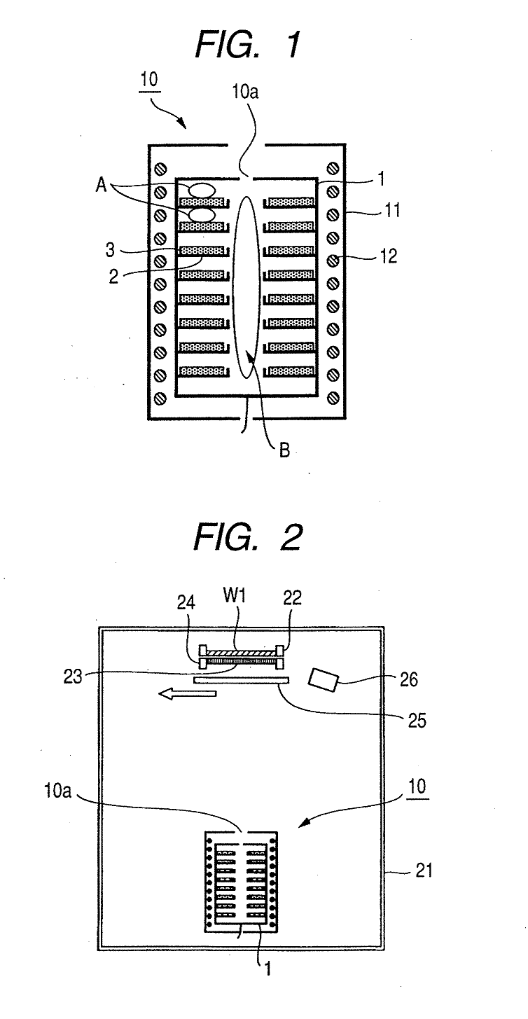

As illustrated in FIG. 1, a vapor deposition source 10 of a vapor deposition apparatus has doughnut-shaped flat plates 2 that form vapor deposition material mounting units stacked in a crucible 1, which is an enclosure. Thin vapor deposition material 3 is mounted on each of the doughnut-shaped flat plates 2. The crucible 1 is disposed in a reflector 11 and heated by heaters 12. Thus, the doughnut-shaped flat plates 2, which are mounting units for mounting the vapor deposition material 3, are stacked in the vertical direction inside the vapor deposition source 10. The doughnut-shaped flat plate 2 on which the vapor deposition material 3 is mounted is made of material, such as graphite, which not only has good heat conductivity in order to maintain the entire plate at a uniform temperature but also has no reactivity with the vapor deposition material 3. To uniformly heat the vapor deposition material 3 and allow the vapor generated from the vapor deposition material 3 to flow, the doughnut-shaped flat plate 2 has a hole at the center.

A gap is provided between each pair of the doughnut-shaped flat plates 2 on which the vapor deposition material 3 is mounted. The gap maintains a flow space A having conductance through which the vapor generated from the vapor deposition material 3 can quickly pass. The vapor generated from the vapor deposition material 3 mounted on each of the doughnut-shaped flat plates 2 flows along the doughnut-shaped flat plate 2 in the radial direction, passes through the central hole and an axial flow path B and reaches an opening 10a that is open at the upper end of the crucible 1. The conductance of the axial flow path B is larger than the conductance of the radial flow space A between the doughnut-shaped flat plates, so that the vapor generated from the vapor deposition material 3 mounted on the doughnut-shaped flat plates 2 can quickly reach the opening 10a. If the conductance of the flow space A is larger than the conductance of the flow path B, the vapor generated from the vapor deposition material mounted on the doughnut-shaped flat plates 2 becomes resistant to flow from the flow space A to the flow path B. Then, variation in pressure in the flow space A causes an unstable vapor deposition rate and bumping. In the present invention, the vapor generated from the vapor deposition material 3 mounted on the doughnut-shaped flat plates 2 can smoothly flow from the flow space to the flow path, allowing a stable vapor deposition rate.

More specifically, the ratio of the conductance C_{A} of the flow space A to the conductance C_{B} of the flow path B can be 1≦C_{B}/C_{A}≦100. The reason for this is that a ratio equal to or smaller than 1 prevents a smooth vapor flow, while a ratio larger than 100 reduces the room for providing the vapor deposition material mounting units.

The conductance mentioned above refers to the reciprocal of flow resistance and is a value indicative of flowability of fluid.

The outer circumference of the doughnut-shaped flat plate 2 on which the vapor deposition material 3 is mounted is attached to the sidewall of the crucible 1 in an individually removable manner. The heaters 12 can be used to heat the outer surface of the crucible 1 so as to uniformly increase the temperature of the whole doughnut-shaped flat plates through heat conduction.

In the present invention, the conductance of the opening 10a can be larger than the conductance of the flow path B, that is, the dimension of the opening 10a can be smaller than the dimension of the hole at the center of the doughnut-shaped flat plate 2. By designing the dimension of the opening 10a to be smaller than the dimension of the hole at the center of the doughnut-shaped flat plate 2, instability of the vapor deposition speed due to variation in time required for the vapor generated from each layer to reach the opening 10a can be eliminated. More specifically, the ratio of the conductance C_{B} of the flow path B to the conductance C₁₀ₐ of the opening 10a can be 1≦C_{B}/C₁₀ₐ≦10. The reason for this is that a ratio equal to or smaller than 1 lowers the vapor deposition rate, while a ratio larger than 10 could allow the heat to escape out of the vapor deposition source so as to affect the substrate to be deposited.

In the present invention, the crucible 1, which is the enclosure, can be disposed above the doughnut-shaped flat plates 2, which are the vapor deposition material mounting units, and the doughnut-shaped flat plates 2 may not be disposed immediately under the opening 10a of the crucible 1 but instead covered with the crucible 1. The reason for this is that if the doughnut-shaped flat plates 2 are disposed immediately under the opening 10a of the crucible 1 and bumping occurs in the vapor deposition material 3 mounted on the doughnut-shaped flat plates 2, particles generated by bumping could directly attach to the substrate to be deposited. In the present invention, even when bumping occurs in the thus mounted vapor deposition material 3, the particles generated by bumping will not directly attach to the substrate to be deposited. Thus, in forming an organic compound layer of an organic EL element, which is very sensitive to foreign matter that contaminates the layer to be formed, a film can be formed with reduced foreign matter therein.

The enclosure disposed above the doughnut-shaped flat plates 2, which are the mounting units, is not necessarily integrated with one of the side and bottom of the enclosure, but may be, for example, a lid-like member removably attached to one of the side and bottom of the enclosure. That is, a member that blocks the doughnut-shaped flat plates 2 from outside environment may be provided. However, a removable member can be used to easily fill the vapor deposition material and clean the inside of the vapor deposition source.

The vapor deposition apparatus illustrated in FIG. 2 includes a substrate holder 22 that holds a substrate to be deposited (substrate) W₁ and a mask holder 24 that holds a mask 23 in a chamber 21 such that the substrate holder 22 and the mask holder 24 face the vapor deposition source 10. Then, the vapor deposition material, such as organic EL film material, in the vapor deposition source 10 is heated to deposit the vapor of the vapor deposition material onto the substrate to be deposited W₁. In this process, the vapor deposition material mounted on the mounting units can be thin. Mounting thin vapor deposition material allows reduction in temperature variation and prevents bumping when the vapor deposition material is heated. Specifically, the vapor deposition material to be mounted can have a thickness of 0.5 mm or more and 10 mm or less.

### First Embodiment

FIG. 1 illustrates a first embodiment, and the crucible 1 is supported by a structure (not illustrated) and heated by the heaters 12 through radiation. A temperature adjuster and a power supply control the power of the heaters 12 by using a thermocouple to measure the temperature at the bottom of the crucible 1. The reflector 11 outside the heaters 12 serves to concentrate the radiant heat from the heaters 12 onto the crucible 1. Thin vapor deposition material 3 is mounted on the doughnut-shaped flat plates 2 overhanging inward from the inner wall of the crucible 1. Each of the doughnut-shaped flat plates 2 is spaced apart by a fixed distance from the adjacent upper and lower doughnut-shaped flat plates 2.

In this embodiment, 1 mm-thick vapor deposition material 3 was mounted on each of the doughnut-shaped flat plates 2. Each doughnut-shaped flat plate 2 has a diameter of 40 mm and a central circular hole having a diameter of 10 mm. Eight doughnut-shaped flat plates 2 were coaxially stacked and 5 mm apart from each other. The flow space A between the doughnut-shaped flat plates 2 is the space through which the vapor generated from the vapor deposition material 3 flows. On the other hand, the diameter of the hole at the center of the doughnut-shaped flat plate 2 is determined such that the flow path B is formed, through which the vapor generated from the vapor deposition material 3 on the doughnut-shaped flat plates 2 easily passes in the axial direction. Thus, the conductance of the flow path B is configured to be larger than the conductance of the flow space A.

The outer circumference of each of the doughnut-shaped flat plates 2 is attached to the inner wall surface of the crucible 1. The opening 10a was disposed coaxially with the doughnut-shaped flat plates 2 and adapted to be a 5 mm-diameter circle.

In the vapor deposition apparatus illustrated in FIG. 2, the vapor deposition source 10 is held at the bottom of the chamber 21. The chamber 21 is connected to an evacuation system (not illustrated), and a pressure meter (also not illustrated) is used to monitor the pressure during evacuation. The opening 10a of the vapor deposition source 10 faces the substrate to be deposited W₁ placed above the vapor deposition source 10. The substrate to be deposited W₁ is held in the substrate holder 22, and the mask 23 is held in the mask holder 24 and in close contact with the film forming surface of the substrate to be deposited W₁. The mask 23 is provided with an open pattern for vapor deposition, which is transferred onto the substrate to be deposited W₁. A shutter 25 is provided between the substrate to be deposited W₁/mask 23 and the vapor deposition source 10. The shutter 25 moves in the direction in which the shutter will be opened when vapor deposition is carried out so as to expose the substrate to be deposited W₁ and the mask 23 to the opening 10a of the vapor deposition source 10.

When the vapor deposition source 10 is heated and the vapor deposition material 3 is being evaporated, a film thickness monitor 26 disposed next to the substrate to be deposited W₁ monitors the vapor deposition rate. The film forming process will be described below.

As the substrate to be deposited W₁, a 100 mm-square quartz glass was placed in the substrate holder 22. As the mask 23, a mask having apertures disposed in a triangle called a delta layout was used. The mask 23 was placed in the mask holder 24 such that the mask 23 comes into close contact with the substrate to be deposited W₁. At this point, the shutter 25 is held at the position where the shutter 25 blocks the vapor deposition surface of the substrate to be deposited W₁. The film thickness monitor 26 used in this embodiment was IC-5 (trade name) made by INFICON. The distance from the opening 10a of the vapor deposition source 10 to the vapor deposition surface of the substrate to be deposited W₁ was 350 mm. The distance from the opening 10a of the vapor deposition source 10 to the vapor deposition surface of the film thickness monitor 26 was also 350 mm. Alq3 was used as the vapor deposition material 3, and 0.05 g of the Alq3 was mounted on each of the doughnut-shaped flat plates 2. After the chamber 21 was evacuated to 1×10⁻⁵ Pa, the heaters 12 were energized to heat the vapor deposition source 10 to 290° C.

When the vapor deposition source 10 reached 290° C., the film thickness monitor 26 was used to confirm that the vapor deposition speed was stable at 14±0.1 nm/sec and the shutter 25 was opened in the open arrow direction to initiate vapor deposition. When the film thickness monitor 26 was used to confirm that the film was formed to a thickness of 200 nm, the shutter 25 was closed to terminate the vapor deposition. Upon the vapor deposition, the thickness of the Alq3 film deposited on the substrate to be deposited W₁ made of quartz glass was measured. The measurement values were 205.1 nm at the center of the substrate and 202.4 nm in average at the centers of the four sides of the substrate that were 50 mm apart from the center of the substrate. The measurement values from the film thickness monitor 26 were observed during the vapor deposition, but there was no steep variation in film forming rate due to bumping (splash) and the like.

Next, in the vapor deposition source similar to that of the first embodiment, the size of the opening of the vapor deposition source was changed and a 10 mm-diameter circular opening was used to carry out vacuum vapor deposition similar to that of the first embodiment. As in the first embodiment, after the substrate to be deposited and the vapor deposition material were placed and the chamber was evacuated to 1×10⁻⁵ Pa, the heaters were energized to heat the vapor deposition source to 290° C. When the vapor deposition source reached 290° C., the film thickness monitor was used to confirm that the vapor deposition speed was stable at 13±0.1 nm/sec and the shutter was opened to initiate vapor deposition. When the film thickness monitor was used to confirm that the film was formed to a thickness of 200 nm, the shutter was closed to terminate the vapor deposition.

The measurement values from the film thickness monitor were observed during the vapor deposition, but there was no steep variation in film forming rate due to bumping. Upon the vapor deposition, the thickness of the Alq3 film deposited on the substrate to be deposited made of quartz glass was measured. The measurement values were 206.2 nm at the center of the substrate and 198.4 nm in average at the centers of the four sides of the substrate that were 50 mm apart from the center of the substrate. That is, the uniformity of the distribution of the deposited film thickness was poorer than that obtained in the first embodiment. This results from the fact that since the opening of the vapor deposition source in this case is larger than that in the first embodiment, the conductance when the vapor of Alq3 passes from the vapor deposition source through the chamber becomes higher and the difference between the pressure inside the vapor deposition source and the pressure outside the vapor deposition source decreases, so that the divergence distribution of the vapor of Alq3 does not follow the cosine rule.

### Second Embodiment

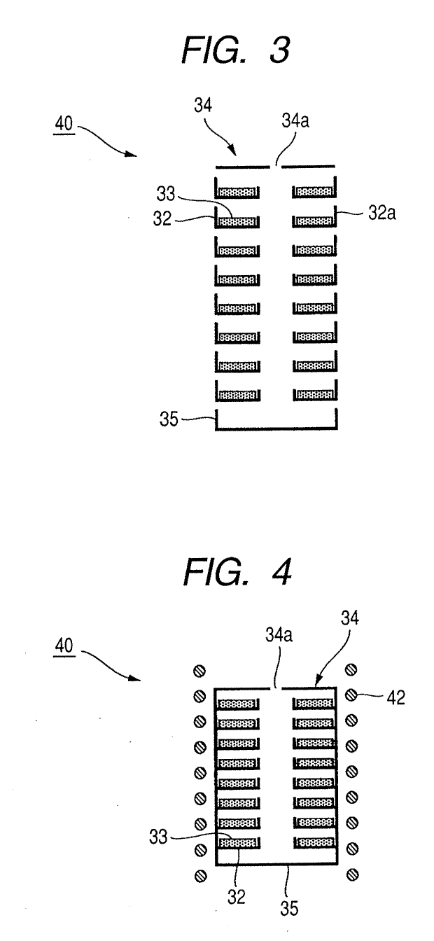

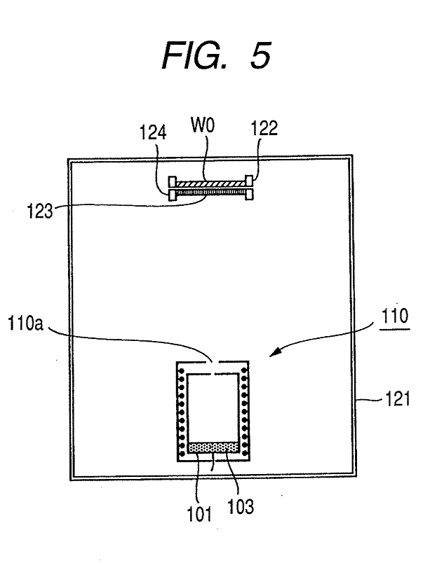

FIGS. 3 and 4 illustrate a vapor deposition source 40 according to the second embodiment. As illustrated in the exploded view of FIG. 3, each doughnut-shaped flat plate 32 of the vapor deposition source 40 has a sidewall 32a, and the doughnut-shaped flat plate 32 integral with the sidewall 32a is separately disposed at each layer. Alq3 is mounted as vapor deposition material 33 on the doughnut-shaped flat plates 32, which are coaxially stacked as illustrated in FIG. 4. Then, a top lid 34 having a center hole 34a is disposed at the top, and a bottom plate 35 is disposed at the bottom. The sidewalls 32a of the stacked doughnut-shaped flat plates 32, the top lid 34 and the bottom plate 35 are adapted such that they have the same function as the crucible 1 in the first embodiment, and then heaters 42 are disposed outside the sidewalls 32a. That is, the vapor deposition source illustrated in FIG. 4 is adapted such that a plurality of structures is vertically stacked, in which the enclosure is integrated with the doughnut-shaped flat plate 32, which are mounting units and each of the structures is independent for each mounting unit. The thus adapted vapor deposition source allows vapor deposition material to be easily mounted on the mounting units and maintenance, such as cleaning and exchange of the vapor deposition source, to be easily carried out.

The vapor deposition source 40 was used to deposit an Alq3 film under the same condition as that in the first embodiment. After the chamber was evacuated to 1×10⁻⁵ Pa, the heaters 42 were energized to heat the vapor deposition source 40 to 290° C. When the vapor deposition source 40 reached 290° C., the film thickness monitor was used to confirm that the vapor deposition speed was stable at 13.5±0.1 nm/sec and the shutter was opened to initiate vapor deposition. When the film thickness monitor was used to confirm that the film was formed to a thickness of 200 nm, the shutter was closed to terminate the vapor deposition.

Upon the vapor deposition, the thickness of the Alq3 film deposited on the substrate to be deposited made of quartz glass was measured. The measurement values were 202.5 nm at the center of the substrate and 200.4 nm in average at the centers of the four sides of the substrate that were 50 mm apart from the center of the substrate. The measurement values from the film thickness monitor were observed during the vapor deposition, but there was no steep variation in film forming rate due to bumping.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2006-077948, filed Mar. 22, 2006, and Japanese Patent Application No. 2007-043094, filed Feb. 23, 2007, which are hereby incorporated by reference herein in their entirety.

What is claimed is:

1. A vapor deposition source that houses vapor deposition material, the vapor deposition source comprising:
an enclosure that houses the vapor deposition material therein and has an opening at the top the enclosure for discharging the vapor deposition material after heated; and
a plurality of mounting units for mounting vapor deposition material, the plurality of mounting units vertically disposed in the enclosure in a multilayer manner with a gap between each pair of mounting units, each of the mounting units being a planar member and having a hole therein,
wherein the gap forms a flow space in the in-plane direction of the mounting unit for guiding the vapor generated from the mounted vapor deposition material to the opening of the enclosure,
the holes of the mounting units form a vertical flow path that connects the flow spaces to the opening of the enclosure, and
the conductance of the flow space is smaller than the conductance of the flow path.

2. The vapor deposition source according to claim 1, wherein the conductance of the opening of the enclosure is smaller than the conductance of the flow path.

3. The vapor deposition source according to claim 1, wherein the enclosure is disposed above the mounting units, and the mounting units are not disposed immediately under the opening of the vapor deposition source but covered with the enclosure.

4. The vapor deposition source according to claim 1, wherein the vapor deposition source is adapted such that a plurality of structures is vertically stacked, in which the enclosure is integrated with the mounting unit and each of the structures is independent for each mounting unit.

5. A vapor deposition apparatus comprising the vapor deposition source according to claim 1, a chamber, a heating unit for heating vapor deposition material mounted in the vapor deposition source and a holding member for holding an object to be deposited.
